(19) United States
(12) Patent Application Publication
(10) Pub. No.: US 2025/0329814 A1
(43) Pub. Date: Oct. 23, 2025

(54) DIN-RAIL, AND ELECTRONIC COMPONENT ASSEMBLY AND ENERGY STORAGE SYSTEM INCLUDING THE SAME

(71) Applicant: LG ENERGY SOLUTION, LTD., Seoul (KR)

(72) Inventors: Jung-Il PARK, Daejeon (KR); Young-Bo CHO, Daejeon (KR)

(73) Assignee: LG ENERGY SOLUTION, LTD., Seoul (KR)

(21) Appl. No.: 18/718,732

(22) PCT Filed: Jul. 24, 2023
(86) PCT No.: PCT/KR2023/010681

§ 371 Date: Nov. 8, 2024

(30) Foreign Application Priority Data
Jul. 25, 2022 (KR) 10-2022-0091541

(51) Int. Cl. H01M 10/6551; H01M 50/691; H05K 7/14

(52) U.S. Cl. CPC H01M 10/6551; H01M 50/691; H05K 7/14324

(57) ABSTRACT

The present disclosure provides a DIN-rail for coupling electronic components including a body disposed on one side of the electronic component and configured to be coupled with the electronic component; and a protector connected to the body, configured to cover an upper part of the electronic component, and configured to discharge fluid so that a fluid falling along a direction of gravity does not contact the electronic component.

### TECHNICAL FIELD

The present disclosure relates to a DIN-rail, and an electronic component assembly and an energy storage system including the same. More specifically, the present disclosure relates to a DIN-rail for fixing electronic components, which may prevent deterioration of the insulation performance of electronic components by applying a structure capable of preventing condensation caused by rapid outdoor environmental changes and draining moisture, and an electronic component assembly and an energy storage system including the same.

The present application claims priority to Korean Patent Application No. 10-2022-0091541 filed on Jul. 25, 2022 in the Republic of Korea, the disclosures of which are incorporated herein by reference.

### BACKGROUND ART

Recently, as issues such as power shortage and eco-friendly energy have emerged, an energy storage system (ESS) for storing generated power has been receiving a lot of attention. Typically, using this energy storage system, it is easy to build a power management system such as a smart grid system, making it possible to easily control power supply in a specific region or city. In addition, as the commercialization of electric vehicles begins in earnest, this energy storage system can also be applied to electric charging stations where electric vehicles can be charged.

The energy storage system may be configured in various forms, but may be typically configured to include one or more battery containers. At this time, the battery container may include a plurality of battery modules connected to each other in series and/or parallel. Here, the plurality of battery modules may be stored inside the battery container through a rack frame or a separate fixing structure. Since the energy storage system including a plurality of battery modules handles a very large amount of power, it essentially includes a circuit breaker that plays a role of protecting circuits and loads by blocking the line when a fault current such as overload, instantaneous current, or phase loss occurs on the electric line, and various electronic components are also included. These electronic components are coupled and fixed to a DIN-rail attached to a switchboard, etc.

However, in existing energy storage systems, there was concern that the insulation performance of electronic components may be deteriorated due to environmental changes or condensation that occurs during the battery cooling process. Therefore, there is a need for a method that can maintain the insulation performance of electronic components and energy storage systems by preventing the inflow of moisture caused by condensation, etc.

### DISCLOSURE

### Technical Problem

The present disclosure is designed to solve the problems of the related art, and therefore the present disclosure is directed to providing a DIN-rail for fixing electronic components, which may prevent the deterioration of the insulation performance of electronic components by applying a structure capable of preventing moisture from entering the electronic components and effectively draining the moisture even if condensation occurs due to, for example, rapid outdoor environmental changes.

Another object of the present disclosure is to provide an electronic component assembly that can prevent deterioration of insulation performance by including this DIN-rail, and an energy storage system including the same.

### Technical Solution

In order to accomplish the above object, a DIN-rail for coupling an electronic component according to an aspect of the present disclosure comprises a body disposed on one side of the electronic component and configured to be coupled with the electronic component; and a protector connected to the body, configured to cover an upper part of the electronic component, and configured to discharge fluid so that a fluid falling along a direction of gravity does not contact the electronic component.

The protector may include a first portion configured to cover the electronic component and configured to collect the fluid; and a second portion configured to extend from the first portion to an outside of the electronic component and configured to discharge the fluid collected by the first portion.

When viewed from above along the direction of gravity, an area of the first portion may be larger than an area of the electronic component so that the electronic component is not exposed to an outside of the first portion.

The first portion may include a first collection space with an embedded shape in a direction toward the electronic component.

A bottom surface of the first collection space may include a downward sloping shape toward the second portion.

The second portion may include a second collection space configured to communicate with the first collection space, and a discharge hole may be formed in a bottom surface of the second collection space to discharge the fluid.

The bottom surface of the second collection space may be formed deeper in the protector than the bottom surface of the first collection space.

The discharge hole may be formed in an area corresponding to an opposite side of the electronic component based on the body unit.

The DIN-rail may include a resin material.

In order to accomplish another object, an electronic component assembly according to the present disclosure comprises the DIN-rail according to the present disclosure.

The electronic component may be a circuit breaker.

In order to accomplish another object, an energy storage system according to the present disclosure comprises the electronic component assembly according to the present disclosure.

The energy storage system may comprise a battery pack including a plurality of batteries; a heat sink coupled to the battery pack and configured to cool the battery pack; and the electronic component configured to collect and discharge fluid generated from the heat sink.

The electronic component assembly may be coupled to at least one of the battery pack and the heat sink.

The electronic component assembly may be located lower than the heat sink along the direction of gravity.

In another embodiment, a DIN-rail for coupling an electronic component can include a body disposed on one side of the electronic component and configured to be coupled with the electronic component; and a protector connected to the body, the protector including a first portion disposed above the electronic component, a second portion extending from the first portion, wherein the protector is connected to one end of the body unit, and wherein the first portion prevents a fluid from contacting the electronic component.

In the protector, the first portion is configured to cover the electronic component and collect the fluid.

Further, the first portion can collect the fluid in a first collection space, the first collection space being wider the closer it is towards the body unit.

The second portion can include a second collection space that communicates with the first collection space.

The DIN-rail can further include a discharge hole formed in a bottom of the second collection space, which discharges the fluid.

Additionally, the first portion can have a larger area when viewed along a direction of gravity than an area of the second portion.

### Advantageous Effects

According to one aspect of the present disclosure, in a DIN-rail that couples electronic components through a body unit, the electronic components can be protected from external physical factors by providing a protection unit. For example, it is possible to protect electronic components from moisture generated by condensation due to rapid changes in temperature, and prevent deterioration of the insulation performance of the electronic components by discharging moisture so that it does not come into contact with the electronic components.

According to another aspect of the present disclosure, since the DIN-rail itself also has insulation performance, it is possible to more effectively prevent deterioration of the insulation performance of electronic components.

According to still another aspect of the present disclosure, electronic components can be more effectively protected from physical external factors, and, for example, moisture resulting from condensation caused by rapid changes in temperature or fluid containing such moisture can be collected and discharged more effectively.

According to still another aspect of the present disclosure, fluid discharged through the discharge hole may not affect electronic components during and after discharge. In other words, according to the present disclosure, efficient discharge of fluid is possible by controlling the discharge direction and location of fluid through the discharge hole.

In addition, the present disclosure may have various other effects, and these will be explained in each embodiment, or the explanation will be omitted for effects that can be easily inferred by a person skilled in the art.

### DESCRIPTION OF DRAWINGS

FIG. 1 is a perspective view showing the appearance of a DIN-rail according to an embodiment of the present disclosure.

FIG. 2 is a top view showing the appearance of the DIN-rail according to an embodiment of the present disclosure.

FIG. 3 is a front view showing the appearance of the DIN-rail according to an embodiment of the present disclosure.

FIG. 4 is a diagram showing an exemplary shape of a cross section cut along line A-A′ in FIG. 1.

FIG. 5 is a diagram schematically showing an electronic component assembly including the DIN-rail according to an embodiment of the present disclosure.

FIG. 6 is a diagram schematically showing an energy storage system including the electronic component assembly according to an embodiment of the present disclosure.

### BEST MODE

Hereinafter, preferred embodiments of the present disclosure will be described in detail with reference to the accompanying drawings. The accompanying drawings illustrate a preferred embodiment of the present disclosure and together with the foregoing disclosure, serve to provide further understanding of the technical features of the present disclosure, and thus, the present disclosure is not construed as being limited to the drawings. Like reference numerals refer to like elements. Additionally, in the drawings, the thickness, proportions and dimensions of components are exaggerated for effective explanation of technical content.

It should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

In this specification, terms indicating directions such as up, down, left, right, front, and back are used, but it is obvious to those skilled in the art of the present disclosure that these terms are only for convenience of explanation and they may vary depending on the location of the target object or the location of the observer.

Accordingly, the embodiments described in this specification and the configurations shown in the drawings are only one of the most preferred embodiments of the present disclosure and do not represent all technical details of the present disclosure, so it should be understood that there may be various equivalents and variations that can be replaced at the time of filing this application.

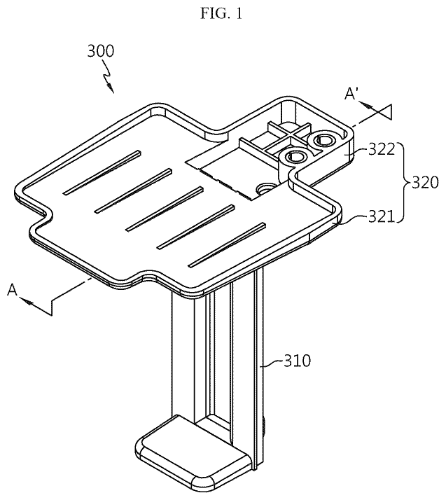

FIG. 1 is a perspective view showing the appearance of a DIN-rail 300 according to an embodiment of the present disclosure.

Referring to FIG. 1, the DIN-rail 300 for fixing electronic components according to an embodiment of the present disclosure includes a body unit 310 and a protection unit 320.

The body unit 310 may be disposed on one side of the electronic component and configured to be coupled with the electronic component. Although not shown in the drawing, a hook structure is provided on one side of the body unit 310 and the electronic component, so that they can be coupled through the hook structure. However, the present disclosure is not limited to such a method of coupling the body unit 310 and the electronic component, and they may be coupled by, for example, screws or bolts and nuts.

The protection unit 320 is connected to the body unit 310 and is configured to cover the upper part of the electronic component, and may be configured to discharge fluid so that the fluid falling along the direction of gravity cannot contact the electronic component. The fluid refers to a fluid that may cause problems such as a short circuit when coming into contact with an electronic component, and for example, it may be a fluid containing moisture. The protection unit 320 may have a substantially plate shape to cover the upper part of the electronic component. The protection unit 320 may be configured to cover the entire upper part of the electronic component. The protection unit 320 is equipped with an inclined structure or a discharge hole to discharge the fluid so that the fluid falling in the direction of gravity cannot contact the electronic component. However, the present disclosure does not limit the shape of the protection unit 320.

According to this configuration in the present disclosure, in the DIN-rail 300, which couples electronic components through the body unit 310, the electronic components can be protected from external physical factors by providing the protection unit 320. For example, it is possible to protect electronic components from condensation that occurs due to rapid changes in temperature, and prevent deterioration of the insulation performance of the electronic components by discharging moisture generated by the condensation so that it does not come into contact with the electronic components.

The DIN-rail 300 may contain a resin material. In this case, since the DIN-rail 300 itself also has insulation performance, deterioration of the insulation performance of electronic components can be more effectively prevented. To maximize this effect, the DIN-rail 300 can be made of a resin material.

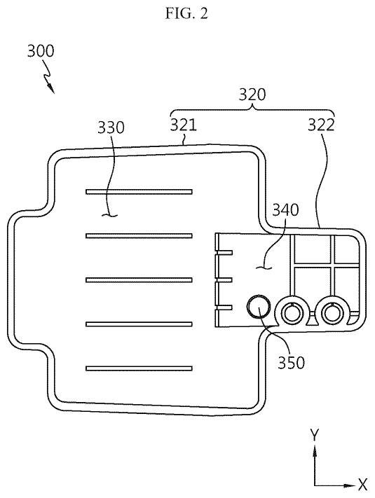

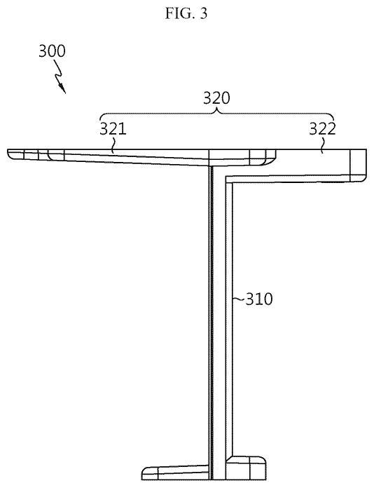

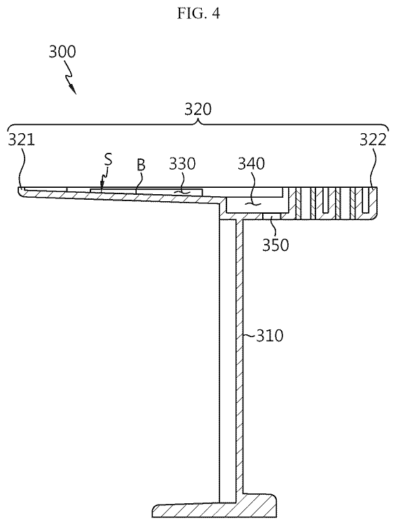

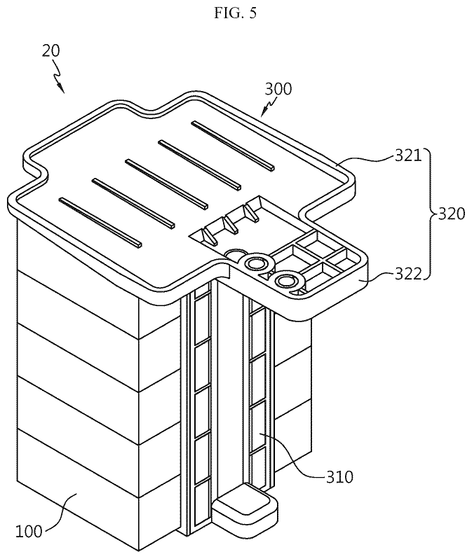

FIG. 2 is a top view showing the appearance of the DIN-rail 300 according to an embodiment of the present disclosure. FIG. 3 is a front view showing the appearance of the DIN-rail 300 according to an embodiment of the present disclosure. FIG. 4 is a diagram showing an exemplary shape of a cross section cut along line A-A′ in FIG. 1. FIG. 5 is a diagram schematically showing an electronic component assembly 20 including the DIN-rail 300 according to an embodiment of the present disclosure.

Referring to FIG. 2, the protection unit 320 may include a first portion 321 and a second portion 322.

Referring to FIGS. 2 and 5, the first portion 321 is configured to cover the electronic component 100 and may be configured to collect fluid. The first portion 321 may have a shape that roughly corresponds to the shape of the upper part of the electronic component 100 so as to effectively cover the electronic component 100. In this case, when viewed from above according to the direction of gravity, the area of the first portion 321 may be larger than the area of the electronic component 100 so that the electronic component 100 is not exposed to the outside of the first portion 321.

The second portion 322 extends from the first portion 321 to the outside of the electronic component 100 and may be configured to discharge the fluid collected by the first portion 321. Referring to FIGS. 2 and 5, the second portion 322 may be formed to extend integrally with the first portion 321, for example. The second portion 322 may be configured so that the fluid collected in the first portion 321 is discharged in the direction of gravity from an extended end located opposite to the first portion 321 with respect to the body unit 310, for example.

According to this configuration of the present disclosure, the electronic component 100 can be more effectively protected from physical external factors, and moisture caused by condensation caused by rapid changes in temperature or fluid containing such moisture can be collected and discharged more effectively.

Referring to FIGS. 2 to 5, the first portion 321 may include a first collection space 330 that is embedded in a direction toward the electronic component 100. The first collection space 330 may be configured such that its internal area other than the perimeter of the first portion 321 is embedded. At least a portion of the bottom surface B of the first collection space 330 may have a downward sloping shape toward the second portion 322. That is, the bottom surface B of the first collection space 330 may include an inclined portion S that is inclined downward along the direction toward the second portion 322. However, the shape of the inclined portion S in the present disclosure is not limited to this, and the inclined portion S may have, for example, a shape in which the bottom surface B of the first collection space 330 is inclined downward along the direction from both ends of the Y-axis extending direction toward the center and also is simultaneously inclined downward in the direction toward the second portion (the positive direction of the X-axis).

Referring to FIGS. 2 to 4, the second portion 322 may include a second collection space 340 configured to communicate with the first collection space 330. The second collection space 340 may be formed deeper than the first collection space 330. Due to the inclined shape of the bottom surface B of the first collection space 330, the fluid is collected, and the fluid may flow to the second collection space 340 by gravity and be collected again.

A discharge hole 350 configured to discharge fluid may be formed in the bottom of the second collection space 340. The discharge hole 350 may be formed in an area corresponding to the opposite side of the electronic component based on the body unit 310. The fluid collected again in the second collection space 340 can be discharged through the discharge hole 350.

According to this configuration of the present disclosure, the fluid discharged through the discharge hole 350 may not affect the electronic component during and after discharge. The fluid can be efficiently discharged by controlling the discharge direction and location of fluid through the discharge hole 350.

Referring to FIG. 5, the electronic component assembly 20 according to an embodiment of the present disclosure may include an electronic component 100 and the DIN-rail 300 according to the present disclosure. In particular, the electronic component 100 may be a circuit breaker.

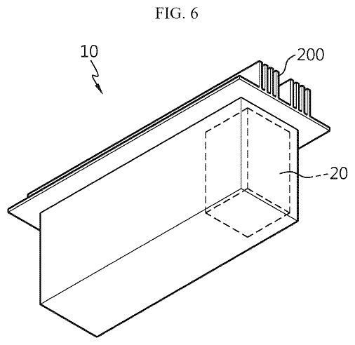

FIG. 6 is a diagram schematically showing an energy storage system 10 including the electronic component assembly 20 according to an embodiment of the present disclosure.

Referring to FIG. 6, the energy storage system 10 according to an embodiment of the present disclosure may include a battery pack including a plurality of secondary batteries, a heat sink 200 coupled to the battery pack and configured to cool the battery pack, and the above-described electronic component assembly 20 according to present disclosure.

The electronic component assembly 20 included in the energy storage system 10 according to an embodiment of the present disclosure may be coupled to at least one of the battery pack and the heat sink 200. Additionally, the electronic component assembly 20 may be located lower than the heat sink 200 along the direction of gravity.

As such, the energy storage system 10 including the electronic component assembly 20 according to this embodiment may include various other components included in the energy storage system in addition to the DIN-rail 10 or the electronic component assembly 20.

As described above, the present disclosure has been described with a focus on preferred embodiments with reference to the accompanying drawings, but it is clear to those skilled in the art that many various obvious modifications can be made from this description without departing from the scope of the present disclosure. Accordingly, the scope of the present disclosure should be construed in terms of the appended claims to include such many modified examples.

### REFERENCE NUMERALS

10: energy storage system
20: electronic component assembly
100: electronic component
200: heat sink
300: DIN-rail
310: body unit
320: protection unit
321: first portion
322: second portion
330: first collection space
340: second collection space
350: discharge hole
B: bottom surface
S: inclined portion

1. A DIN-rail for coupling an electronic component, comprising:
a body disposed on one side of the electronic component and configured to be coupled with the electronic component; and
a protector connected to the body, configured to cover an upper part of the electronic component, and configured to discharge fluid so that a fluid falling along a direction of gravity does not contact the electronic component.

2. The DIN-rail according to claim 1, wherein the protector includes:
a first portion configured to cover the electronic component and configured to collect the fluid; and
a second portion configured to extend from the first portion to an outside of the electronic component and configured to discharge the fluid collected by the first portion.

3. The DIN-rail according to claim 2, wherein when viewed from above along the direction of gravity, an area of the first portion is larger than an area of the electronic component so that the electronic component is not exposed to an outside of the first portion.

4. The DIN-rail according to claim 2, wherein the first portion includes a first collection space with an embedded shape in a direction toward the electronic component.

5. The DIN-rail according to claim 4, wherein a bottom surface of the first collection space includes a downward sloping shape toward the second portion.

6. The DIN-rail according to claim 4, wherein the second portion includes a second collection space configured to communicate with the first collection space, and
wherein a discharge hole is formed in a bottom surface of the second collection space to discharge the fluid.

7. The DIN-rail according to claim 6, wherein the bottom surface of the second collection space is formed deeper in the protector than the bottom surface of the first collection space.

8. The DIN-rail according to claim 6, wherein the discharge hole is formed in an area corresponding to an opposite side of the electronic component based on the body.

9. The DIN-rail according to claim 1, wherein the DIN-rail includes a resin material.

10. An electronic component assembly, comprising:
an electronic component; and
the DIN-rail according to claim 1, which is coupled to the electronic component.

11. The electronic component assembly according to claim 10, wherein the electronic component is a circuit breaker.

12. An energy storage system, comprising:
a battery pack including a plurality of batteries;
a heat sink coupled to the battery pack and configured to cool the battery pack; and
the electronic component assembly according to claim 10, which is configured to collect and discharge fluid generated from the heat sink.

13. The energy storage system according to claim 12, wherein the electronic component assembly is coupled to at least one of the battery pack and the heat sink.

14. The energy storage system according to claim 12, wherein the electronic component assembly is located lower than the heat sink along the direction of gravity.

15. A DIN-rail for coupling an electronic component, comprising:
a body disposed on one side of the electronic component and configured to be coupled with the electronic component; and
a protector connected to the body, the protector comprising:
a first portion disposed above the electronic component, and
a second portion extending from the first portion,
wherein the protector is connected to one end of the body, and
wherein the first portion prevents a fluid from contacting the electronic component.

16. The DIN-rail according to claim 15, wherein the first portion is configured to cover the electronic component and collect the fluid.

17. The DIN-rail according to claim 16, wherein the first portion collects the fluid in a first collection space, the first collection space being wider the closer it is towards the body.

18. The DIN-rail according to claim 17, wherein the second portion includes a second collection space that communicates with the first collection space.

19. The DIN-rail according to claim 18, further comprising a discharge hole formed in a bottom of the second collection space, which discharges the fluid.

20. The DIN-rail according to claim 15, wherein the first portion has a larger area when viewed along a direction of gravity than an area of the second portion.
